(19) United States
(12) Patent Application Publication
(10) Pub. No.: US 2026/0033368 A1
(43) Pub. Date: Jan. 29, 2026

(54) ELECTRONIC DEVICE

(71) Applicant: Advanced Semiconductor Engineering, Inc., Kaohsiung (TW)

(72) Inventors: Chih Lung HUNG, Kaohsiung (TW); Hsin-Hua HUANG, Kaohsiung (TW); Kuofeng HUANG, Kaohsiung (TW)

(73) Assignee: Advanced Semiconductor Engineering, Inc., Kaohsiung (TW)

(21) Appl. No.: 18/784,853

(22) Filed: Jul. 25, 2024

(51) Int. Cl. H01L 23/498; H01L 21/56; H01L 23/00; H01L 23/367; H01L 23/538; H01L 25/065

(52) U.S. Cl. CPC H01L 23/49844; H01L 23/5386; H01L 21/56; H01L 23/3672; H01L 24/32; H01L 24/48; H01L 24/73; H01L 25/0655; H01L 2224/16; H01L 2224/16225; H01L 2224/32225; H01L 2224/48225; H01L 2224/73257; H01L 2224/73265; H01L 2924/13055

(57) ABSTRACT

An electronic device and a method of manufacturing an electronic device are provided. The electronic device includes a first conductive layer and a first power die. The first conductive layer including a first part and a second part separated from the first part. The first power die is disposed above the first conductive layer and has a first surface. The first power die includes a first terminal exposed from the first surface and a second terminal exposed from the first surface. The first part is electrically connected to the first terminal and the second part is electrically connected to the second terminal.

### BACKGROUND

### 1. Field of the Disclosure

The present disclosure relates to an electronic device and a method of manufacturing an electronic device.

### 2. Description of the Related Art

As the power output from power modules increases, heat dissipation becomes more challenging.

### SUMMARY

In some embodiments, an electronic device electronic device includes a first conductive layer and a first power die. The first conductive layer including a first part and a second part separated from the first part. The first power die is disposed above the first conductive layer and has a first surface. The first power die includes a first terminal exposed from the first surface and a second terminal exposed from the first surface. The first part is electrically connected to the first terminal and the second part is electrically connected to the second terminal.

In some embodiments, an electronic device includes a first conductive layer, a second conductive layer, a first die, and a second die. The second conductive layer is disposed over the first conductive layer and includes a first part extending toward the first conductive layer. The first die is disposed between the first conductive layer and the second conductive layer. A distance between the first conductive layer and the second conductive layer is substantially equal to a thickness of the first die. The second die is disposed between the first conductive layer and the second conductive layer and electrically connected to the first die through the first part.

In some embodiments, an electronic device includes a first die, a second die, and a first conductive layer. The second die is disposed adjacent to the first die. The first conductive layer includes a first part supporting the first die and a second part disposed at a lateral side of the first die. The second die is electrically connected to the first die through the second part.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 is a cross-sectional view of an electronic device according to some embodiments of the present disclosure.

FIG. 2 is an explosive view of an electronic device according to some embodiments of the present disclosure.

FIG. 3 is a cross-sectional view of an electronic device according to some embodiments of the present disclosure.

FIG. 4 is a cross-sectional view of an electronic device according to some embodiments of the present disclosure.

FIG. 4A is an enlarged cross-sectional view of a box A1 in FIG. 4.

FIG. 4B is another enlarged cross-sectional view of a box A1 in FIG. 4.

FIG. 4C is yet another enlarged cross-sectional view of a box A1 in FIG. 4.

FIG. 5 is a circuit diagram of an electronic device according to some embodiments of the present disclosure.

FIG. 6 is an explosive view of an electronic device according to some embodiments of the present disclosure.

FIG. 7 is a top view of conductive layers of an electronic device according to some embodiments of the present disclosure.

FIG. 8 is a cross-sectional view of an electronic device according to some embodiments of the present disclosure.

FIGS. 9A, 9B, 9C, 9D, and 9E illustrate one or more stages of an example of a method for manufacturing an electronic device according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

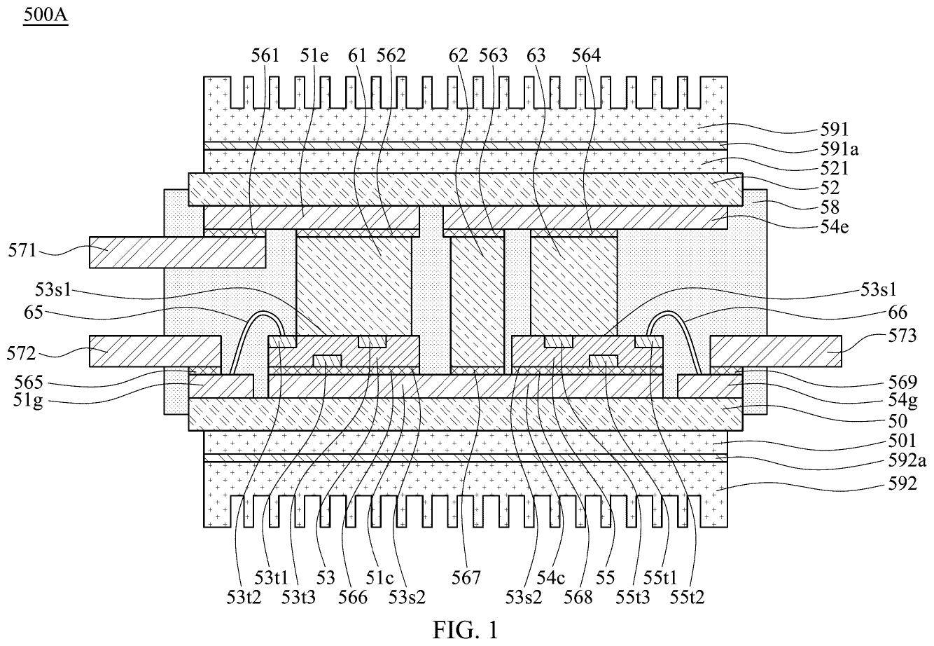

FIG. 1 is a cross-sectional view of an electronic device 500A according to some embodiments of the present disclosure. The electronic device 500A may include a dielectric layer 50, a conductive layer 501, a dielectric layer 52, a conductive layer 521, a heat dissipation structure 591, and a heat dissipation structure 592.

The conductive layer 501 may be disposed below the dielectric layer 50. The heat dissipation structure 592 may be disposed below the conductive layer 501. The dielectric layer 50 may be connected to the conductive layer 501. The conductive layer 501 may be connected to the heat dissipation structure 592 through a thermal adhesive layer 592a. The conductive layer 521 may be disposed below the dielectric layer 52. The heat dissipation structure 591 may be disposed below the conductive layer 521. The dielectric layer 52 may be connected to the conductive layer 521. The conductive layer 521 may be connected to the heat dissipation structure 591 through a thermal adhesive layer 591a. The dielectric layer 50 and the dielectric layer 52 may be disposed between the heat dissipation structure 591 and the heat dissipation structure 592. The heat dissipation structure 591 may be configured to dissipate heat from the electronic device 500A to an external environment. The heat dissipation structure 592 may be configured to dissipate heat from the electronic device 500A to an external environment. The heat dissipation structure 591 and the heat dissipation structure 592 may be configured to dissipate heat through opposite sides of the electronic device 500A. The heat dissipation structure 591 and the heat dissipation structure 592 may be double-sided heat dissipation structures.

The material of the dielectric layer 50 and the dielectric layer 52 may include, for example, an organic material, such as a solder mask, a polyimide (PI), an Ajinomoto build-up film (ABF), and one or more molding compounds. The material of the dielectric layer 50 and the dielectric layer 52 may include, for example, an inorganic material silicon-oxide (SiOₓ), or a silicon-nitride (SiNₓ). In some embodiments, the conductive layer 501 and the conductive layer 521 may be formed of metal or metal alloy. The conductive layer 501 and the conductive layer 521 may include metal, such as copper, gold, silver, aluminum, titanium, tantalum, or the like.

The heat dissipation structures 591 and 592 may include a heat sink, such as heat dissipation fins, a cooling channel, or a heat dissipation plate. The thermal adhesive layer 591a and the thermal adhesive layer 592a may include a heat dissipation gel.

The electronic device 500A may further include a conductive layer 51c, a conductive layer 51g, a conductive layer 51e, a die 53, a conductive layer 54c, a conductive layer 54g, a conductive layer 54e, a die 55, connection elements 561, 562, 563, 564, 565, 566, 567, 568, and 569, conductive elements 571, 572, and 573, an encapsulating layer 58, spacers 61, 62, and 63, and bond wirings 65 and 66. The above-mentioned elements may be disposed between the dielectric layer 50 and the dielectric layer 52.

The conductive layer 51g and the conductive layer 51c may be disposed over the dielectric layer 50. The conductive layer 51g and the conductive layer 51c may be connected to the dielectric layer 50. The conductive layer 51g and the conductive layer 51c may be disposed below the die 53. The conductive layer 51e may be disposed below the dielectric layer 52. The conductive layer 51e may be connected to the dielectric layer 52. The conductive layer 51e may be disposed over the die 53.

In some embodiments, the conductive layer 51c, the conductive layer 51g, and the conductive layer 51e may be formed of metal or metal alloy. The conductive layer 51c, the conductive layer 51g, and the conductive layer 51e may include metal, such as copper, gold, silver, aluminum, titanium, tantalum, or the like.

The die 53 may be disposed over the conductive layer 51g and the conductive layer 51c. The die 53 may overlap the conductive layer 51c. The die 53 may be free from overlapping the conductive layer 51g. The die 53 may have a top surface 53s1 facing the conductive layer 51e and a bottom surface 53s2 facing the conductive layer 51g and the conductive layer 51c. The die 53 may have a collector terminal 53t1, a gate terminal 53t2, and an emitter terminal 53t3. The collector terminal 53t1 may be at the bottom surface 53s2, and the gate terminal 53t2 and the emitter terminal 53t3 may be at the top surface 53s1. The die 53 may include an insulated gate bipolar transistor (IGBT) or a power transistor. The die 53 may include a plurality of IGBTs connected in parallel.

The conductive layer 51g may be electrically connected to the gate terminal 53t2 through the bond wiring 65. The gate terminal 53t2 may be higher than the conductive layer 51g with respect to the dielectric layer 50. In some embodiments, the bond wiring 65 may have a first end connected to the gate terminal 53t2 and a second end connected to the conductive layer 51g and lower than the first end with respect to the dielectric layer 50. The bond wiring 65 may have a curved shape.

The conductive layer 51e may be electrically connected to the emitter terminal 53t3 through the spacer 61. The spacer 61 may be disposed over the top surface 53s1 of the die 53. The spacer 61 may be connected to the conductive layer 51e through the connection element 562. The spacer 61 may have relatively high thermal conductivity compared to that of the encapsulating layer 58. The spacer 61 may be configured to dissipate heat from the die 53 to the dielectric layer 52, the conductive layer 521, and the heat dissipation structure 591. The spacer 61 may be used to increase the space between the conductive layer 51e and the die 53. The bond wiring 65 can extend in the space without directly contacting the conductive layer 51e or the conductive element 571. This prevents short circuit between the bond wiring 65 and the conductive layer 51c or between the bond wiring 65 and the conductive element 571.

The conductive layer 51c may be electrically connected to the collector terminal 53t1 through the connection elements 566. The conductive layer 51c may have a first part connected to the die 53 and a second part connected to the spacer 62 through the connection element 567. The first part and the second part of the conductive layer 51c may have the same thickness in the cross-sectional view. The first part may be seamlessly connected to the second part of the conductive layer 51c. The spacer 62 may be connected to the conductive layer 54e through the connection element 563. The spacer 62 may have relatively high thermal conductivity compared to that of the encapsulating layer 58. The spacer 62 may be configured to dissipate heat from the die 53 and the die 55. The height of the spacer 62 may be higher than that of the spacer 61 and the spacer 62.

The conductive layer 54g and the conductive layer 54c may be disposed over the dielectric layer 50. The conductive layer 54g and the conductive layer 54c may be connected to the dielectric layer 50. The conductive layer 54g and the conductive layer 54c may be disposed below the die 55. The conductive layer 54e may be disposed below the dielectric layer 52. The conductive layer 54e may be connected to the dielectric layer 52. The conductive layer 54e may be disposed over the die 55.

In some embodiments, the conductive layer 54c, the conductive layer 54g, and the conductive layer 54e may be formed of metal or metal alloy. The conductive layer 54c, the conductive layer 54g, and the conductive layer 54e may include metal, such as copper, gold, silver, aluminum, titanium, tantalum, or the like.

The die 55 may be disposed over the conductive layer 54g and the conductive layer 54c. The die 55 may overlap the conductive layer 54c. The die 55 may be free from overlapping the conductive layer 54g. The die 55 may have a top surface 55s1 facing the conductive layer 54c and a bottom surface 55s2 facing the conductive layer 54g and the conductive layer 54e. The die 55 may have a collector terminal 55t1, a gate terminal 55t2, and an emitter terminal 55t3. The collector terminal 55t1 may be at the bottom surface 55s2, and the gate terminal 55t2 and the emitter terminal 55t3 may be at the top surface 55s1. The die 55 may include an IGBT or a power transistor. The die 55 may include a plurality of IGBTs connected in parallel.

The conductive layer 54g may be electrically connected to the gate terminal 55t2 through the bond wiring 66. The gate terminal 55t2 may be higher than the conductive layer 54g with respect to the dielectric layer 50. In some embodiments, the bond wiring 66 may have a first end connected to the gate terminal 55t2 and a second end connected to the conductive layer 54g and lower than the first end with respect to the dielectric layer 50. The bond wiring 66 may have a curved shape.

The conductive layer 54e may be electrically connected to the emitter terminal 55t3 through the spacer 63. The spacer 63 may be disposed over the top surface 55s1 of the die 55. The spacer 63 may be connected to the conductive layer 54e through the connection element 564. The spacer 63 may have relatively high thermal conductivity compared to that of the encapsulating layer 58. The spacer 63 may be configured to dissipate heat from the die 55 to the dielectric layer 52, the conductive layer 521, and the heat dissipation structure 591. The spacer 63 may be used to increase the space between the conductive layer 54e and the die 55. The bond wiring 66 can extend in the space without directly contacting the conductive layer 54e. This prevents short circuit between the bond wiring 65 and the conductive layer 54e.

The conductive layer 54e may have a first part connected to the die 55 and a second part connected to the spacer 62 through the connection element 563. The first part and the second part of the conductive layer 54e may have the same thickness in the cross-sectional view. The first part of the conductive layer 54e may be seamlessly connected to the second part of the conductive layer 54e. The spacer 62 may be connected to the conductive layer 54e through the connection element 563.

The conductive layer 54c may be electrically connected to the collector terminal 55t1 through the connection elements 568. The connection elements 566, 567, and 568 may be at the same elevation. The connection elements 562, 563, and 564 may be at the same elevation.

The die 55 and the die 53 are connected in series. The emitter terminal 55t3 of the die 55 may be electrically connected to the collector terminal 53t1 of the die 53 through the conductive layer 54e, the spacer 62, and the conductive layer 51c. The transistor of the die 55 may be a high side power switch. The transistor of the die 53 may be a low side power switch.

In some embodiments, the spacer 61, the spacer 62, and the spacer 63 may be formed of metal or metal alloy. The spacer 61, the spacer 62, and the spacer 63 may include metal, such as copper, gold, silver, aluminum, titanium, tantalum, or the like. In some embodiments, the connection elements 561, 562, 563, 564, 565, 567, 568, and 569 may include solder balls, controlled collapse chip connection (C4) bumps, a ball grid array (BGA), or a land grid array (LGA).

The conductive element 571 may be partially disposed under the conductive layer 51e. The conductive element 571 may be connected to the conductive layer 51e through the connection element 561. The conductive element 571 may be electrically connected to the emitter terminal 53t3 of the die 53 through the spacer 62 and the conductive layer 51e.

The conductive element 572 may be partially disposed over the conductive layer 51g. The conductive element 572 may be connected to the conductive layer 51g through the connection element 565. The conductive element 572 may be electrically connected to the gate terminal 53t2 of the die 53 through the conductive layer 51g.

The conductive element 573 may be partially disposed over the conductive layer 54g. The conductive element 573 may be connected to the conductive layer 54g through the connection element 569. The conductive element 573 may be electrically connected to the gate terminal 55t2 of the die 55 through the conductive layer 54g.

The conductive elements 571, 572, and 573 may form a lead frame. The conductive elements 571, 572, and 573 may include metal, such as copper, gold, silver, aluminum, titanium, tantalum, or the like.

The encapsulating layer 58 may be disposed between the dielectric layer 50 and the dielectric layer 52. The encapsulating layer 58 may be disposed over the dielectric layer 50. The encapsulating layer 58 may be disposed below the dielectric layer 52. A part of a lateral surface of each of the dielectric layer 50 and the dielectric layer 52 may be covered by the encapsulating layer 58.

The encapsulating layer 58 may be formed by transfer molding. In some embodiments, the encapsulating layer 58 may include an epoxy resin including fillers, a molding compound (e.g., an epoxy molding compound or other molding compound), polyimide, a phenolic compound or material, a material including silicone dispersed therein, or a combination thereof.

The encapsulating layer 58 may encapsulate the die 53, the die 55, the spacers 61, 62, and 63, the conductive layers 51c, 51g, and 51e, and the conductive layers 54c, 54g, and 54e. The conductive elements 571, 572, and 573 may protrude from the encapsulating layer 58. The conductive elements 571, 572, and 573 may be electrically connected to an external device (e.g., a printed circuit board).

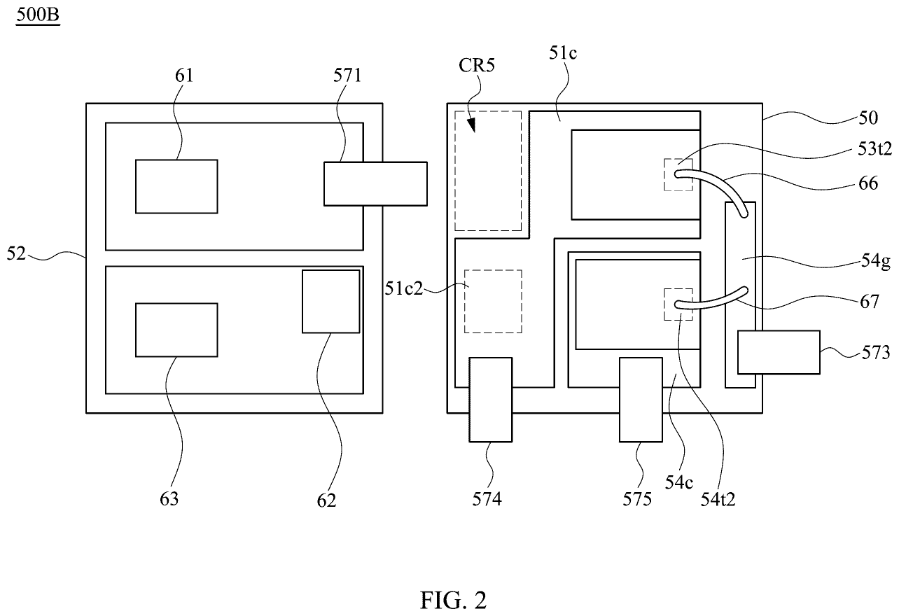

FIG. 2 is an explosive view of an electronic device 500B according to some embodiments of the present disclosure. The electronic device 500B may include the dielectric layer 50, the dielectric layer 52, the die 53, the die 55, the conductive layers 51g, 51c, and 51e, the conductive layers 54g, 54c, and 54e, the conductive elements 571, 573, 574, and 575, the spacers 61, 62, and 63, and the bond wirings 66 and 67.

As shown in FIG. 2, a first structure including the dielectric layer 52, the conductive layers 51e and 54e, the conductive element 571, and the spacers 61, 62, and 63 may be viewed in a bottom view. As shown in FIG. 2, a second structure including the dielectric layer 50, the die 53, the die 55, the conductive layers 51g and 51c, the conductive layers 54g and 54c, and the conductive elements 573, 574, and 575 may be view in a top view. The first structure can be flipped over to face the second structure. Thus, the spacer 61 is aligned with the die 53, the spacer 63 is aligned with the die 55, and the spacer 62 is aligned with a second part 51c2 of the conductive layer 51c. The conductive layer 51c may have an irregular shape. The conductive layer 51c may have an area larger than the conductive layers 54c and have a first part connected to the die 53 and a second part 51c2 connected to the spacer 62. The conductive layer 51c may define a clearance region CR5 aligned with the conductive element 571. The conductive element 571 may be electrically connected to the conductive layer 51e.

The conductive element 573 may be electrically connected to the conductive layer 54g. The gate terminal 53t2 of the die 53 and the gate terminal 55t2 of the die 55 may be electrically connected to the conductive layer 54g through the bond wirings 66 and 67, respectively. The gate terminal 53t2 and the gate terminal 55t2 may be configured to receive the same control signal through conductive element 573.

The conductive element 574 may be electrically connected to the conductive layer 51c. The conductive element 575 may be electrically connected to the conductive layer 54c.

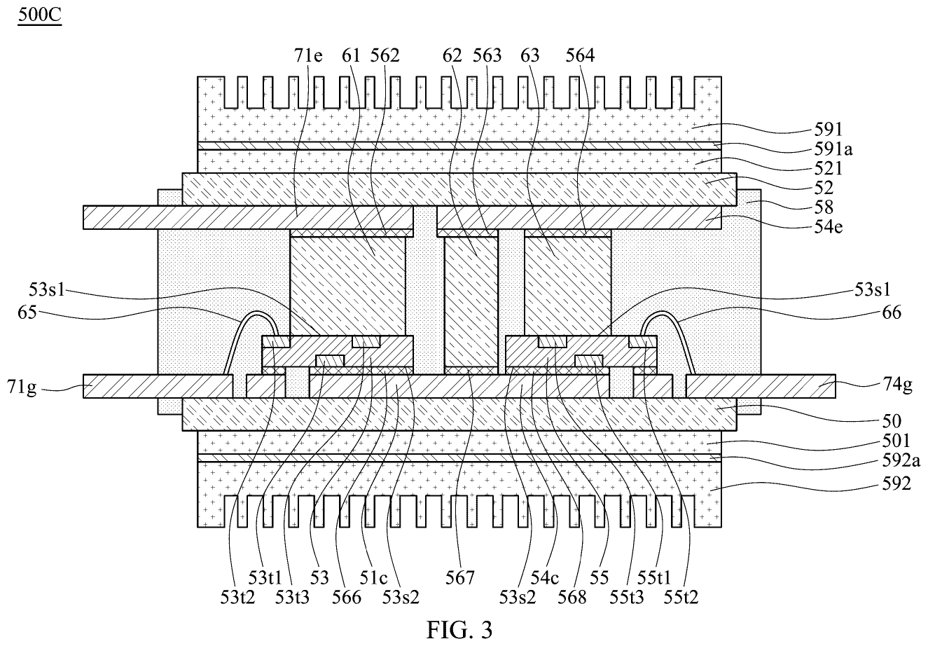

FIG. 3 is a cross-sectional view of an electronic device 500C according to some embodiments of the present disclosure. The electronic device 500C in FIG. 3 is similar to the electronic device 500A in FIG. 1. Therefore, some detailed descriptions may refer to corresponding preceding paragraphs and are not repeated hereinafter for conciseness, with differences therebetween as follows.

The electronic device 500C may include a conductive layer 71e rather than the conductive layer 51e of the electronic device 500A. The conductive layer 71e may be electrically connected to the emitter terminal 53t3 of the die 53. The conductive layer 71e may partially overlap the die 53 in a direction perpendicular to the bottom surface 53s2 of the die 53. The conductive layer 71e may protrude from the encapsulating layer 58. The conductive layer 71e may have an end outside the encapsulating layer 58. The conductive layer 71e may be connected to an external device. Therefore, no lead frame for connecting the die 53 to an external device is required.

The electronic device 500C may further include a conductive layer 71g rather than the conductive layer 51g of the electronic device 500A. The conductive layer 71g may be electrically connected to the gate terminal 53t2 of the die 53 through the bond wiring 65. The conductive layer 71g may protrude from the encapsulating layer 58. The conductive layer 71g may have an end outside the encapsulating layer 58. The conductive layer 71g may be connected to an external device. Therefore, no lead frame for connecting the die 53 to an external device is required.

The electronic device 500C may further include a conductive layer 74g rather than the conductive layer 54g of the electronic device 500A. The conductive layer 74g may be electrically connected to the gate terminal 55t2 of the die 55 through the bond wiring 66. The conductive layer 74g may protrude from the encapsulating layer 58. The conductive layer 74g may have an end outside the encapsulating layer 58. The conductive layer 74g may be connected to an external device. Therefore, no lead frame for connecting the die 55 to an external device is required.

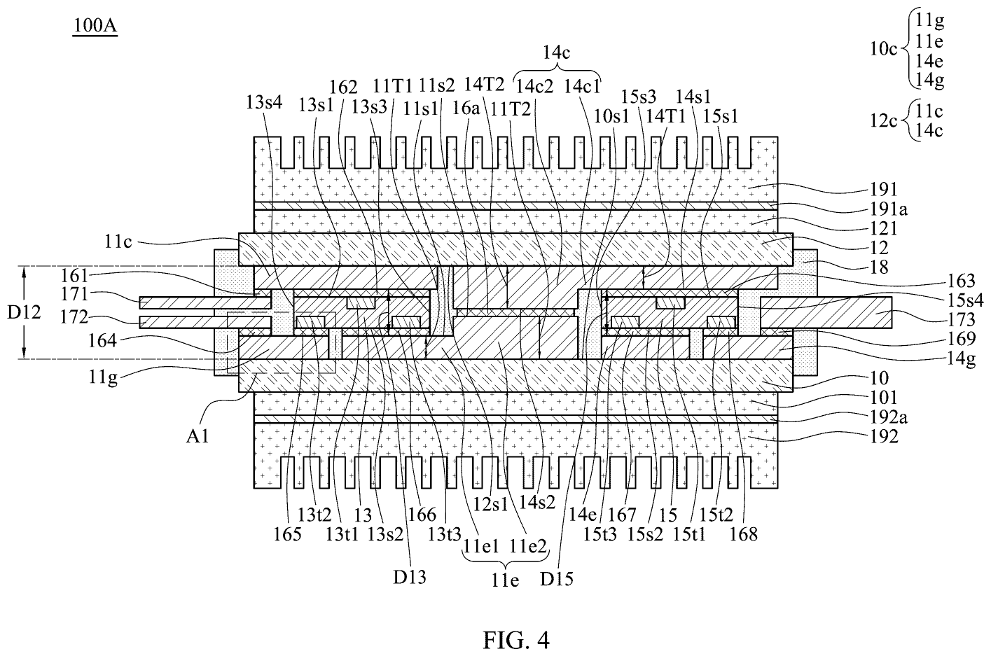

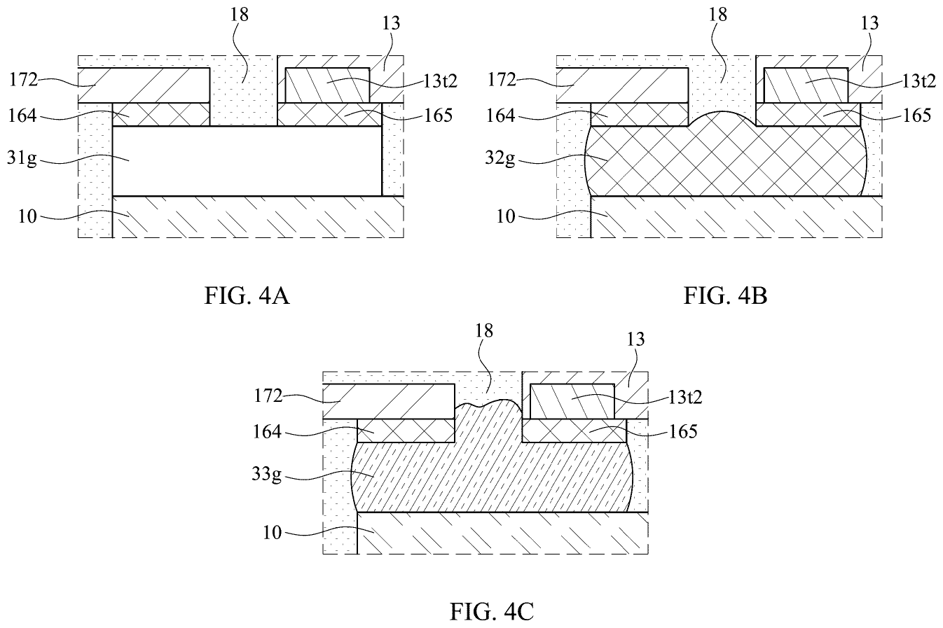

FIG. 4 is a cross-sectional view of an electronic device according to some embodiments of the present disclosure. The electronic device 100A may include a dielectric layer 10, a conductive layer 101, a dielectric layer 12, a conductive layer 121, a heat dissipation structure 191, and a heat dissipation structure 192.

The conductive layer 101 may be disposed below the dielectric layer 10. The heat dissipation structure 192 may be disposed below the conductive layer 101. The dielectric layer 10 may be connected to the conductive layer 101. The conductive layer 101 may be connected to the heat dissipation structure 192 through a thermal adhesive layer 192a. The conductive layer 121 may be disposed below the dielectric layer 12. The heat dissipation structure 191 may be disposed below the conductive layer 121. The dielectric layer 12 may be connected to the conductive layer 121. The conductive layer 121 may be connected to the heat dissipation structure 191 through a thermal adhesive layer 191a. The dielectric layer 10 may have a surface 10s1 facing a surface 12s1 of the dielectric layer 12. The dielectric layer 10 and the dielectric layer 12 may be disposed between the heat dissipation structure 191 and the heat dissipation structure 192. The heat dissipation structure 191 may be configured to dissipate heat from the electronic device 100A to an external environment. The heat dissipation structure 192 may be configured to dissipate heat from the electronic device 100A to an external environment. The heat dissipation structure 191 and the heat dissipation structure 192 may be configured to dissipate heat through opposite sides of the electronic device 100A. The heat dissipation structure 191 and the heat dissipation structure 192 may be double-sided heat dissipation structures.

The material of the dielectric layer 10 and the dielectric layer 12 may include, for example, an organic material, such as a solder mask, a polyimide (PI), an Ajinomoto build-up film (ABF), and one or more molding compounds. The material of the dielectric layer 10 and the dielectric layer 12 may include, for example, an inorganic material silicon-oxide (SiOₓ), or a silicon-nitride (SiNₓ). In some embodiments, the conductive layer 101 and the conductive layer 121 may be formed of metal or metal alloy. The conductive layer 101 and the conductive layer 121 may include metal, such as copper, gold, silver, aluminum, titanium, tantalum, or the like.

The heat dissipation structures 191 and 192 may include a heat sink, such as heat dissipation fins, a cooling channel, or a heat dissipation plate. The thermal adhesive layer 191a and the thermal adhesive layer 192a may include a heat dissipation gel.

The electronic device 100A may further include a conductive layer 11c, a conductive layer 11g, a conductive layer 11e, a die 13, a conductive layer 14c, a conductive layer 14g, a conductive layer 14e, a die 15, connection elements 161, 162, 163, 164, 165, 166, 167, 168, and 169, and 16a, conductive elements 171, 172, and 173, and an encapsulating layer 18. The above-mentioned elements may be disposed between the dielectric layer 10 and the dielectric layer 12.

The conductive layer 11g and the conductive layer 11e may be disposed over the dielectric layer 10. The surface 10s1 of the dielectric layer 10 may be in contact with the conductive layer 11e. The conductive layer 11g and the conductive layer 11e may be connected to the dielectric layer 10. The conductive layer 11g and the conductive layer 11e may be disposed below the die 13. The conductive layer 11c may be disposed below the dielectric layer 12. The conductive layer 11c may be connected to the dielectric layer 12. The conductive layer 11c may be disposed over the die 13.

In some embodiments, the conductive layer 11c, the conductive layer 11g, and the conductive layer 11e may be formed of metal or metal alloy. The conductive layer 11c, the conductive layer 11g, and the conductive layer 11e may include metal, such as copper, gold, silver, aluminum, titanium, tantalum, or the like.

The die 13 may be disposed over the conductive layer 11g and the conductive layer 11e. The die 13 may partially overlap the conductive layer 11e in a direction perpendicular to the surface 10s1 of the dielectric layer 10. The die 13 may partially overlap the conductive layer 11g in a direction perpendicular to the surface 10s1 of the dielectric layer 10. The die 13 may have an upper surface (or a surface) 13s1 facing the conductive layer 11c and a bottom surface (or a surface) 13s2 facing the conductive layer 11g and the conductive layer 11e. The die 13 may have a terminal (or a collector terminal) 13t1, a terminal (or a gate terminal) 13t2, and a terminal (or an emitter terminal) 13t3. The collector terminal 13t1 may be at the upper surface 13s1, and the gate terminal 13t2 and the emitter terminal 13t3 may be at the lower surface 13s2. The collector terminal 13t1 may be exposed by the upper surface 13s1. The gate terminal 13t2 and the emitter terminal 13t3 may be exposed by the lower surface 13s2. The die 13 may include a power die. The die 13 may include an insulated gate bipolar transistor (IGBT) or a power transistor. The die 13 may include a plurality of IGBTs connected in parallel.

The die 13 may be disposed adjacent to the die 15. The die 13 may have a lateral surface 13s3 facing the die 15 and a lateral surface 13s4 opposite to the lateral surface 13s3. The lateral surface 13s3 extends between the upper surface 13s1 and the lower surface 13s2. The lateral surface 13s4 extends between the upper surface 13s1 and the lower surface 13s2.

The conductive layer 11g may be disposed adjacent to the conductive layer 11e. The conductive layer 11g may be electrically connected to the gate terminal 13t2 through the connection element 165. The conductive element 172 may be partially disposed over the conductive layer 11g. The conductive element 172 may be connected to the conductive layer 11g through the connection element 164. The conductive element 172 may be electrically connected to the gate terminal 13t2 of the die 13 through the conductive layer 11g.

The conductive layer 11c may be electrically connected to the collector terminal 13t1 through the connection elements 162. The conductive element 171 may be partially disposed under the conductive layer 11c. The conductive element 171 may be connected to the conductive layer 11c through the connection element 161. The conductive element 171 may be electrically connected to the collector terminal 13t1 of the die 13 through the conductive layer 11c.

The conductive element 171 may be disposed over the conductive element 172. The conductive element 171 may be spaced apart from the conductive element 172. The conductive elements 171, 172, and 173 may form a lead frame. The conductive elements 171, 172, and 173 may configured to receive a signal external to the electronic device 100A. The conductive elements 171, 172, and 173 may configured to transmit signal to an external device. The conductive elements 171, 172, and 173 may include metal, such as copper, gold, silver, aluminum, titanium, tantalum, or the like.

The conductive layer 14g and the conductive layer 14e may be disposed over the dielectric layer 10. The conductive layer 14g and the conductive layer 14e may be connected to the dielectric layer 10. The conductive layer 14g and the conductive layer 14e may be disposed below the die 11. The conductive layer 14c may be disposed below the dielectric layer 12. The conductive layer 14c may be connected to the dielectric layer 12. The conductive layer 14c may be disposed over the die 15.

In some embodiments, the conductive layer 14c, the conductive layer 14g, and the conductive layer 14e may be formed of metal or metal alloy. The conductive layer 14c, the conductive layer 14g, and the conductive layer 14e may include metal, such as copper, gold, silver, aluminum, titanium, tantalum, or the like.

The die 15 may be disposed over the conductive layer 14g and the conductive layer 14e. The die 15 may overlap the conductive layer 14e. The die 15 may partially overlap the conductive layer 14g. The die 15 may have an upper surface (or a surface) 15s1 facing the conductive layer 14c and a lower surface 15s2 facing the conductive layer 14g and the conductive layer 14e. The die 15 may have a terminal (or a collector terminal) 15t1, a terminal (or a gate terminal) 15t2, and a terminal (or an emitter terminal) 15t3. The collector terminal 15t1 may be at the lower surface 15s2, and the gate terminal 15t2 and the emitter terminal 15t3 may be at the upper surface 15s1. The collector terminal 15t1 may be exposed by the upper surface 15s1. The gate terminal 15t2 and the emitter terminal 15t3 may be exposed by the lower surface 15s2. The die 15 may include a power die. The die 15 may include an IGBT or a power transistor. The die 15 may include a plurality of IGBTs connected in parallel.

The die 15 may have a lateral surface 15s3 facing the die 13 and a lateral surface 15s4 opposite to the lateral surface 15s3. The lateral surface 15s3 extends between the upper surface 15s1 and the lower surface 15s2. The lateral surface 15s4 extends between the upper surface 15s1 and the lower surface 15s2.

The conductive layer 14g may be disposed adjacent to the conductive layer 14e. The conductive layer 14g may be electrically connected to the gate terminal 15t2 through the connection element 168. The conductive element 173 may be partially disposed over the conductive layer 14g. The conductive element 173 may be connected to the conductive layer 14g through the connection element 169. The conductive element 173 may be electrically connected to the gate terminal 15t2 of the die 15 through the conductive layer 14g.

The conductive layer 14e may be electrically connected to the emitter terminal 15t3 through the connection element 167. The conductive layer 14e may be connected to a conductive element (not shown).

The die 13 and the die 15 are connected in series. In some embodiments, the IGBTs of the die 13 and the die 15 are connected in series. The die 13 may be electrically connected to the die 15 through the conductive layer 11e and the conductive layer 14c. The emitter terminal 13t3 of the die 13 may be electrically connected to the collector terminal 15t1 of the die 15 through the conductive layer 11e and the conductive layer 14c. The transistor of the die 13 may be a high side power switch. The transistor of the die 15 may be a low side power switch.

The conductive layer 11e may extend along the lower surface 13s2 and the lateral surface 13s3 of the die 13. The conductive layer 11e may have a first part 11e1 connected to the die 13 and a second part 11e2 connected to the die 15. The first part 11e1 may be disposed directly below the die 13 and the second part 11e2 may be disposed between the die 13 and the die 15 in a cross-sectional view. The second part 11e2 may extend between the lateral surface 13s3 of the die 13 and the lateral surface 15s3 of the die 15. The conductive layer 11e may be formed in one piece. The first part 11e1 may be seamlessly connected to the second part 11e2.

The conductive layer 11e may be electrically connected to the emitter terminal 13t3 through, e.g., the connection element 166. The first part 11e1 may be connected to the emitter terminal 13t3. The second part 11e2 may be connected to the conductive layer 14c. The second part 11e2 may be electrically connected to the die 15. The second part 11e2 may electrically connect to the upper surface 15s1 of the die 15.

The second part 11e2 may protrude toward the conductive layer 14c. A first thickness 11T1 of the first part 11e1 may be different from a second thickness 11T2 of the second part 11e2. In some embodiments, the second thickness 11T2 may be greater than the first thickness 11T1. The conductive layer 11e may have a first upper surface 11s1 and a second upper surface 11s2 at different elevations with respect to the surface 10s1 of the dielectric layer 10. An imaginary extension line of the second upper surface 11s2 of the conductive layer 11e may pass through the die 13 and the die 15 in a cross-sectional view.

The conductive layer 14c may extend along the upper surface 15s1 and the lateral surface 15s3 of the die 15. The conductive layer 14c may have a first part 14cl connected to the die 15 and a second part 14c2 connected to the die 13. The first part 14cl may be disposed directly over the die 15 and the second part 14c2 may be disposed between the die 13 and the die 15 in a cross-sectional view. The second part 14c2 may extend between the lateral surface 13s3 of the die 13 and the lateral surface 15s3 of the die 15. The conductive layer 14c may be formed in one piece. The first part 14cl may be seamlessly connected to the second part 14c2.

The conductive layer 14c may be electrically connected to the collector terminal 15t1, e.g., through the connection element 163. The first part 14cl may be connected to the collector terminal 15t1. The second part 14c2 of the conductive layer 14c may be connected to the second part 11e2 of the conductive layer 11e. The second part 14c2 may be electrically connected to the die 13. The die 13 may be electrically connected to the die 15 through the second part 11e2 of the conductive layer 11e and the second part 14c2 of the conductive layer 14c. The second part 14c2 may electrically connect to the lower surface 13s2 of the die 13.

The second part 14c2 may protrude toward the conductive layer 11e. A third thickness 14T1 of the first part 14cl may be different from a fourth thickness 14T2 of the second part 14c2. In some embodiments, the fourth thickness 14T2 may be greater than the third thickness 14T1. The conductive layer 14c may have a first bottom surface 14s1 and a second bottom surface 14s2 at different elevations with respect to the surface 10s1 of the dielectric layer 10. An imaginary extension line of the second bottom surface 14s2 of the conductive layer 14c may pass through the die 13 and the die 15 in a cross-sectional view.

The connection element 16a may connect the conductive layer 11e to the conductive layer 14c. The connection element 16a may be disposed between the second part 11e2 of the conductive layer 11e and the second part 14c2 of the conductive layer 14c. The connection element 16a may be disposed between the die 13 and the die 15. A first elevation of the connection element 16a may be between a second elevation of the lower surface 13s2 of the die 13 and a third elevation of the upper surface 13s1 of the die 13. The connection element 166 may be disposed between the die 13 and the first part 11e1 of the conductive layer 11e. The connection element 167 may be disposed between the die 15 and the conductive layer 14e. A first elevation of the connection element 166 disposed on the first part 11e1 may be lower than a second elevation of the connection element 16a disposed on the second part 11e2 with respect to the lower surface 13s2 of the die 13.

A third elevation of the connection element 167 disposed on the conductive layer 14e may be lower than the second elevation of the connection element 16a. The first elevation may be substantially the same as the third elevation.

In some embodiments, the conductive layer 11e may be rotationally symmetrical to the conductive layer 14c. In some embodiments, by rotating the conductive layer 11e 180 degrees with respect to the connection element 16a, the shape of the conductive layer 11e may match that of the conductive layer 14c. By rotating the conductive layer 14c 180 degrees with respect to the connection element 16a, the shape of the conductive layer 14c may match that of the conductive layer 11e.

The conductive layer 11e may have relatively high thermal conductivity compared to that of the encapsulating layer 18. The conductive layer 14c may have relatively high thermal conductivity compared to that of the encapsulating layer 18. The conductive layer 11e and/or the conductive layer 14c may be configured to dissipate heat from the die 13 to the dielectric layer 10, the conductive layer 101, and the heat dissipation structure 192. The conductive layer 11e and/or the conductive layer 14c may be configured to dissipate heat from the die 13 to the dielectric layer 12, the conductive layer 121, and the heat dissipation structure 191. The second part 11e2 of the conductive layer 11e and the second part 14c2 of the conductive layer 14c may be configured to dissipate heat from the die 13 and the die 15.

In some embodiments, the electronic device 100A may include a first conductive layer 10c and a second conductive layer 12c disposed over the first conductive layer 10c. The first conductive layer 10c may be disposed over the dielectric layer 10. The first conductive layer 10c may include the conductive layers 11g, 11e, 14e, and 14g, each of which may refer to a part of the first conductive layer 10c. In other words, the first conductive layer 10c may include a part 11g, a part 11e1, a part 11e2, a part 14e, and a part 14g. The second conductive layer 12c may disposed over the dielectric layer 12. The second conductive layer 12c may include the conductive layers 11c and 14c, each of which may refer to a part of the second conductive layer 12c. In other words, the second conductive layer 12c may include a part 11c, a part 14c2, and a part 14cl.

The part 11e1 of the first conductive layer 10c may be separated from the part 11g. The part 11e1 may extend from the part 11e2. The part 14e may be separated from the part 14g. The part 11e1 or 11e2 may be separated from the part 14e. The part 11c of the second conductive layer 12c may be separated from the part 14c2. The part 14cl may extend from the part 14c2.

The die 13 or the die 15 may be disposed between first conductive layer 10c and the second conductive layer 12c. In some embodiments, the die 13 may include the connection elements 162, 165, and 166. A distance between the first conductive layer 10c (or the part 11e1 or 11g) and the second conductive layer 12c (or the part 11c) is substantially equal to a thickness D13 of the die 13. In some embodiments, the die 15 may include the connection elements 163, 167, and 168. A distance between the first conductive layer 10c (or the part 14e or 14g) and the second conductive layer 12c (or the part 14c1) is substantially equal to a thickness D15 of the die. The die 13 may be disposed between the part 11e1 and the second conductive layer 12c. The die 15 may be disposed between the part 14cl and the first conductive layer 10c.

The die (or the power die) 13 may be disposed above the first conductive layer 10c. The part 11e1 of the first conductive layer 10c may support the die 13 and the part 11e2 of the first conductive layer 10c may be disposed at a lateral side (e.g., the side adjacent to the lateral surface 13s3) of the die 13.

The die (or the power die) 15 may be disposed above the first conductive layer 10c. The second conductive layer 12c may be disposed above the die 13 and the die 15. The part 14cl of the second conductive layer 12c may support the die 15 and the part 14c2 of the second conductive layer 12c may be disposed at a lateral side (e.g., the side adjacent to the lateral surface 15s3) of the die 15.

The part 11g and the part 11e1 of the first conductive layer 10c may be electrically connected to different functional terminals of the die 13, respectively. The part 11g of the first conductive layer 10c may be electrically connected to the terminal 13t2, and the part 11e1 of the first conductive layer 10c may be electrically connected to the terminal 13t3. The part 14g and the part 14e of the first conductive layer 10c may be electrically connected to different functional terminals of the die 15, respectively. The part 14e of the first conductive layer 10c may be electrically connected to the terminal 15t3. The part 14g of the first conductive layer 10c may be electrically connected to the terminal 15t2.

The part 11c of the second conductive layer 12c may be electrically connected to the terminal 13t1. The part 14cl of the second conductive layer 12c may be electrically connected to the terminal 15t1.

The die 15 may be electrically connected to the die 13 through the second conductive layer 12c (e.g., the part 14c2) and/or the first conductive layer 10c (e.g., the part 11e2). The part 11e2 of the first conductive layer 10c may be electrically connected to the terminal 15t1 of the die 15. The part 11e2 of the first conductive layer 10c may extend toward the second conductive layer 12c. The part 14c2 of the second conductive layer 12c may be electrically connected to the terminal 13t3 of the die 13. The part 14c2 of the second conductive layer 12c may extend toward the first conductive layer 10c. The terminal 13t3 may be electrically connected to the terminal 15t1 through the part 14c2 and/or the part 11e2. The emitter terminal 13t3 of the die 13 may be electrically connected to the collector terminal 15t1 of the die 15.

The connection element 16a may connecting the first conductive layer 10c and the second conductive layer 12c. The part 11e2 of the first conductive layer 10c may connect to the part 14c2 of the second conductive layer 12c, e.g., through the connection element 16a.

In some cases, a power device may include at least one terminal of a die connected to a conductive layer through a spacer, which has a relatively large Z height. The spacer would elongate the thermal dissipation path in the power device, and degrade the thermal dissipation efficiency. In the present disclosure, all of the terminals of the dies 13 and 15 are connected to the conductive layers (e.g., 10c and 12c) without an extra spacer. The thermal dissipation path in the electronic device 100A can be shortened, and thus the thermal dissipation efficiency can be improved. Furthermore, the Z height of the electronic device 100A can be reduced, as can the cost of manufacturing the electronic device 100A.

Furthermore, each of the first conductive layer 10c and the second conductive layer 12c has multiple thicknesses. The total thickness of the part 14c2 and the part 11e2 may be substantially the same as a distance D12 between the dielectric layer 10 and the dielectric layer 12. The high side emitter terminal (e.g., 13t3) of the die 13 can be connected to the low side collector terminal (e.g., 15t1) of the die 15 through the thicker part 11c2 of the second conductive layer 12c and the thicker part 11e2 of the first conductive layer 10c.

In addition, the part 11c is disposed on the dielectric layer 12, and the parts 11g and 11e are disposed on the different dielectric layer 10. The part 11c may have a relatively large contact area with the dielectric layer 12, and thus the thermal dissipation efficiency from the collector terminal 13t1 to the dielectric layer 12 can be improved. Similarly, the part 14c is disposed on the dielectric layer 12, and the parts 14g and 14e are disposed on the different dielectric layer 10. The part 14c may have a relatively large contact area with the dielectric layer 12, and thus the thermal dissipation efficiency from the collector terminal 15t1 to the dielectric layer 12 can be improved.

In some embodiments, the connection elements 161, 162, 163, 164, 165, 167, 168, 169, and 16a may include solder balls, controlled collapse chip connection (C4) bumps, a ball grid array (BGA), or a land grid array (LGA). In some embodiments, the connection element may include an interposer.

The encapsulating layer 18 may be disposed between the dielectric layer 10 and the dielectric layer 12. The encapsulating layer 18 may be disposed over the dielectric layer 10. The encapsulating layer 18 may be disposed below the dielectric layer 12. A part of a lateral surface of each of the dielectric layer 10 and the dielectric layer 12 may be covered by the encapsulating layer 18.

The encapsulating layer 18 may be formed by transfer molding. In some embodiments, the encapsulating layer 18 may include an epoxy resin including fillers, a molding compound (e.g., an epoxy molding compound or other molding compound), polyimide, a phenolic compound or material, a material including silicone dispersed therein, or a combination thereof.

The encapsulating layer 18 may encapsulate or cover the die 13, the die 15, the conductive layers 11c, 11g, and 11e, and the conductive layers 14c, 14g, and 14e. The conductive elements 171, 172, and 173 may protrude from the encapsulating layer 18. The conductive elements 171, 172, and 173 may be electrically connected to an external device (e.g., a printed circuit board).

FIG. 4A is an enlarged cross-sectional view of a box A1 in FIG. 4. The part 11g of electronic device 100A may include a conductive structure 31g for bridging the conductive element 172 and the terminal 13t2 of the die 13. The conductive structure 31g may be disposed between the conductive element 172 and the terminal 13t2. The conductive structure 31g may be disposed over the dielectric layer 10. The conductive structure 31g may include, such as, a conductive layer, a circuit layer, a bridging die, a solder, a conductive paste, etc.

FIG. 4B is another enlarged cross-sectional view of a box A1 in FIG. 4. The part 11g of electronic device 100A may include a conductive structure 32g for bridging the conductive element 172 and the terminal 13t2 of the die 13. The material of the conductive structure 32g may include a solder material, controlled collapse chip connection (C4) bumps, a ball grid array (BGA), or a land grid array (LGA). The conductive structure 32g may have a portion extending between the connection element 164 and the connection element 165.

FIG. 4C is yet another enlarged cross-sectional view of a box A1 in FIG. 4. The part 11g of electronic device 100A may include a conductive structure 33g for bridging the conductive element 172 and the terminal 13t2 of the die 13. The material of the conductive structure 33g may include a conductive paste, a conductive glue or any other suitable materials. The material of the conductive structure 33g may include conductive particles and an adhesive layer encapsulating the conductive particles. The conductive structure 33g may have a step structure. The higher portion of the step structure is disposed between the connection element 164 and the connection element 165 and the lower portion of the step structure is disposed between the connection element 164 and the connection element 165. The portion (or the higher portion) of the part 11g may be disposed at the lateral surface 13s4 of the die 13.

In some embodiments, the conductive element 173 may be electrically connected to the terminal 15t2 of the die 15 through a conductive structure similar to the conductive structure 31g, 32g, or 33g. In some embodiments, the conductive element 171 may be electrically connected to the terminal 13t1 of the die 13 through a conductive structure similar to the conductive structure 31g, 32g, or 33g.

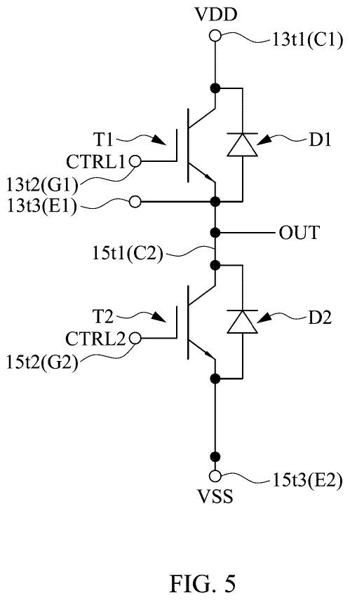

FIG. 5 is a circuit diagram of an electronic device (e.g., the electronic device 100A) according to some embodiments of the present disclosure. The electronic device 100A may include a transistor T1 and a transistor T2 connected in series. The transistor T1 may be included in the die 13. The transistor T1 may have a collector terminal 13t1 (C1) connected to a voltage supply VDD, a gate terminal 13t2 (G1) configured to receive a control signal CTRL1, and an emitter terminal 13t3 (E1) connected to an output OUT. The transistor T1 may be a high side power switch.

The transistor T2 may be included in the die 15. The transistor T2 may have a collector terminal 15t1 (C2) connected to the output OUT and the emitter terminal 13t3 (E1) of the transistor T1, a gate terminal 15t2 (G2) configured to receive a control signal CTRL2, and an emitter terminal 15t3 (E2) connected to a voltage supply VSS (or the ground). The control signal CTRL1 may be the same as the control signal CTRL2. The transistor T1 may be a low side power switch.

The transistor T1 may be connected with a diode D1. The diode D1 may be an anti-parallel diode. The transistor T2 may be connected with a diode D2. The diode D2 may be an anti-parallel diode. The diode D1 or the diode D2 may provide a path for the reverse current to flow when the transistor T1 or the transistor T2 turns off. The diode D1 or the diode D2 may clamp the inductive reverse voltage spike when the transistor T1 or the transistor T2 turns off.

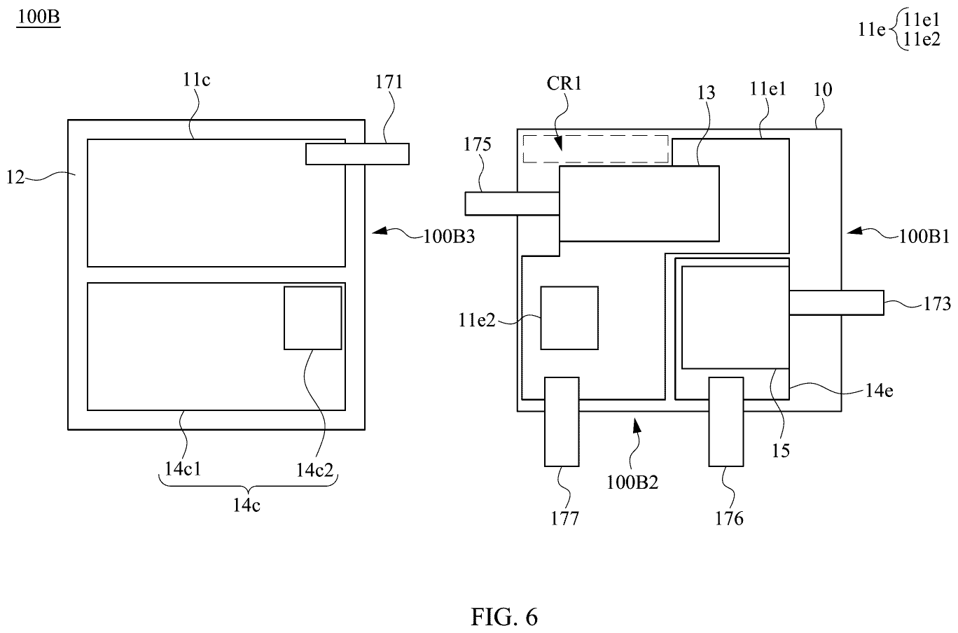

FIG. 6 is an explosive view of an electronic device 100B according to some embodiments of the present disclosure. The electronic device 100B may include the dielectric layer 10, the dielectric layer 12, the die 13, the die 15, the conductive layers 11g, 11c, and 11e, the conductive layers 14g, 14c, and 14e, and the conductive elements 171, 173, 175, 176, and 177.

As shown in FIG. 6, a first structure including the dielectric layer 12, the conductive layers 11c and 14c, and the conductive element 171 may be viewed in a bottom view. As shown in FIG. 6, a second structure including the dielectric layer 10, the die 13, the die 15, the conductive layers 11g and 11e, the conductive layers 14g and 14e, and the conductive elements 173, 175, 176, and 177 may be view in a top view. The first structure can be flipped over to face the second structure. Thus, the conductive layer 11c is aligned with the die 13, the conductive layer 14c is aligned with the die 15, and the second part 14c2 of the conductive layer 14c is aligned with the second part 11e2 of the conductive layer 11e. The first part 14cl may have an area larger than the second part 14c2 in the bottom view. The first part 11e1 may have an irregular shape. The first part 11e1 may have an area larger than the second part 11e2 in the top view. The conductive layer 11e may have an area larger than the conductive layer 14e and have the first part 11e1 connected to the die 13. The conductive layer 11e may define a clearance region CRI aligned with the conductive element 171. The conductive element 171 may be electrically connected to the conductive layer 11c.

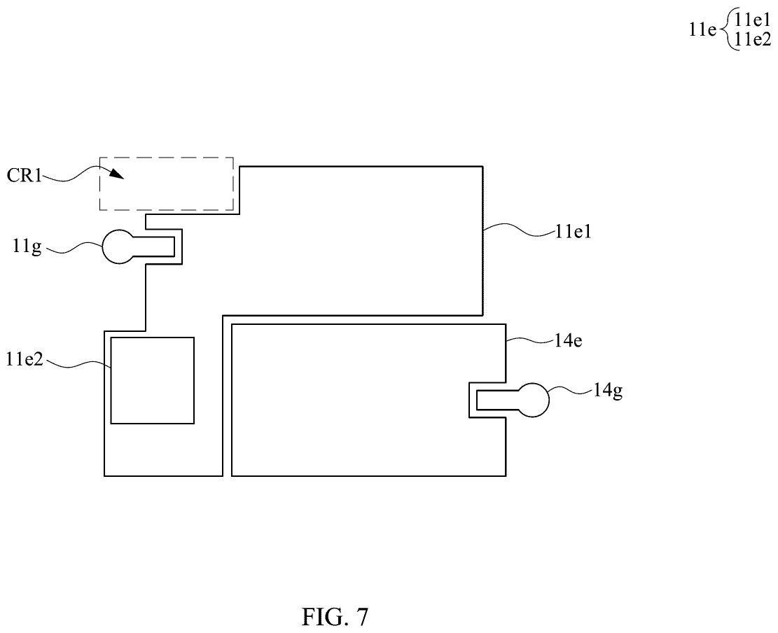

FIG. 7 is a top view of conductive layers 11e, 11g, 14e, and 14g of an electronic device (e.g., the electronic device 100B) according to some embodiments of the present disclosure. The conductive layer 11e may be spaced part from the conductive layer 11g. The conductive layer 14e may be spaced part from the conductive layer 14g. Each of the conductive layer 11g and the conductive layer 14g may have a round end and a rectangular end opposite to the round end. The round end is farther away from the conductive layer 11e (or 14e) than the rectangular end. The rectangular end may be surrounded by the conductive layer 11e (or 14e), while the round end protrudes from the conductive layer 11e (or 14e).

According to FIG. 6 and FIG. 7, the conductive element 173 may be electrically connected to the conductive layer 14g. The conductive element 175 may be electrically connected to the conductive layer 11g. The conductive element 176 may be electrically connected to the conductive layer 14e. The conductive element 177 may be electrically connected to the conductive layer 11e. In some embodiments, the conductive element 173 and the conductive element 176 may be configured to connect an external device at different side of the electronic device 100B (e.g., a side 100B1 and a side 100B2). The side 100B1 and the side 100B2 may face in different directions. In some embodiments, the conductive element 172 may be configured to connect an external device at a side 100B3 of the electronic device 100B. The side 100B3 is different from the side 100B1 and the side 100B2. In some embodiments, a conductive element (e.g., the conductive element 171 in FIG. 4) may be configured to connect an external device at the same side (e.g., the side 100B3) as the conductive element 172.

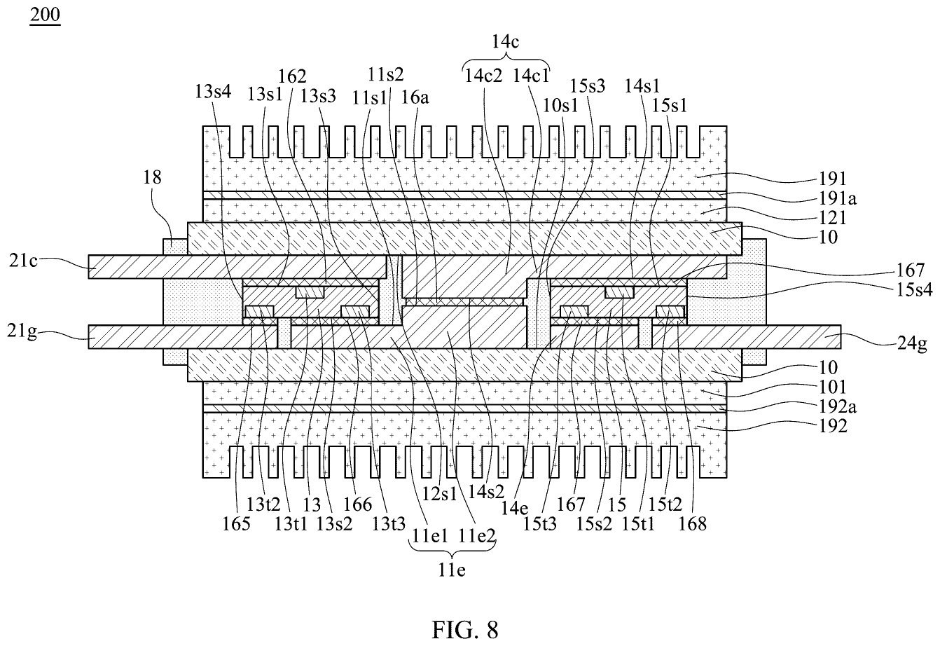

FIG. 8 is a cross-sectional view of an electronic device 200 according to some embodiments of the present disclosure. The electronic device 200 in FIG. 8 is similar to the electronic device 100A in FIG. 4. Therefore, some detailed descriptions may refer to corresponding preceding paragraphs and are not repeated hereinafter for conciseness, with differences therebetween as follows.

The electronic device 200 may include a conductive layer 21c rather than the conductive layer 11c of the electronic device 100A. The conductive layer 21c may be electrically connected to the collector terminal 13t1 of the die 13 through the connection element 162. The conductive layer 21c may partially overlap the die 13 in a direction perpendicular to the lower surface 13s2 of the die 13. The conductive layer 21c may protrude from the encapsulating layer 18. The conductive layer 21c may have an end outside the encapsulating layer 18. The conductive layer 21c may be connected to an external device. Therefore, no lead frame for connecting the die 13 to an external device is required.

The electronic device 200 may further include a conductive layer (or a part) 21g rather than the conductive layer 11g of the electronic device 200. The conductive layer 21g may be disposed adjacent to the conductive layer 11e. The conductive layer 21g may be spaced apart from the condcutive layer 11e. The conductive layer 21g may be electrically connected to the gate terminal 13t2 of the die 13 through the connection element 165. The conductive layer 21g may protrude from the encapsulating layer 18. The conductive layer 21g may have an end outside the encapsulating layer 18. The conductive layer 21g may be connected to an external device. Therefore, no lead frame for connecting the die 13 to an external device is required.

The electronic device 200 may further include a conductive layer 24g rather than the conductive layer 14g of the electronic device 200. The conductive layer 24g may be disposed adjacent to the conductive layer 14e. The conductive layer 24g may be spaced apart from the condcutive layer 14e. The conductive layer 24g may be electrically connected to the gate terminal 15t2 of the die 15 through the connection element 168. The conductive layer 24g may protrude from the encapsulating layer 18. The conductive layer 24g may have an end outside the encapsulating layer 18. The conductive layer 24g may be connected to an external device. Therefore, no lead frame for connecting the die 15 to an external device is required.

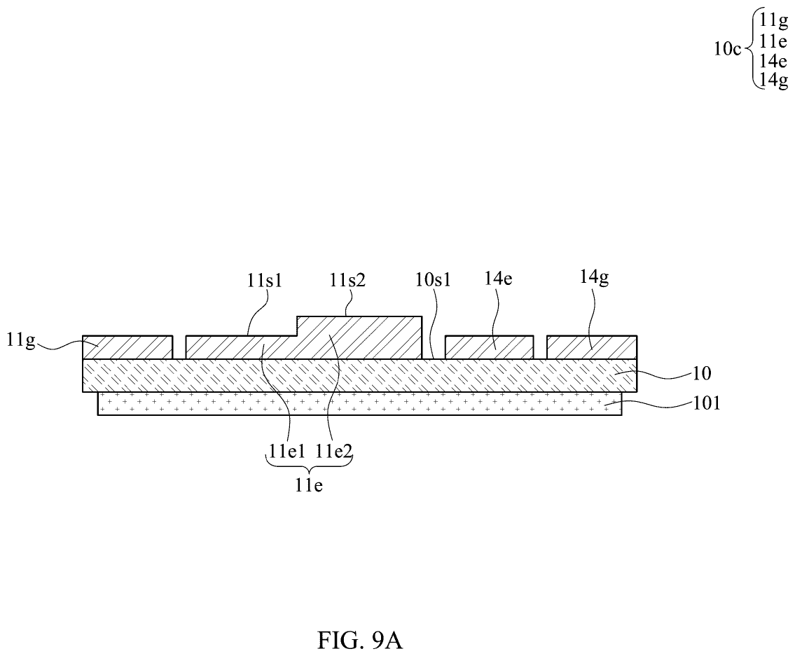

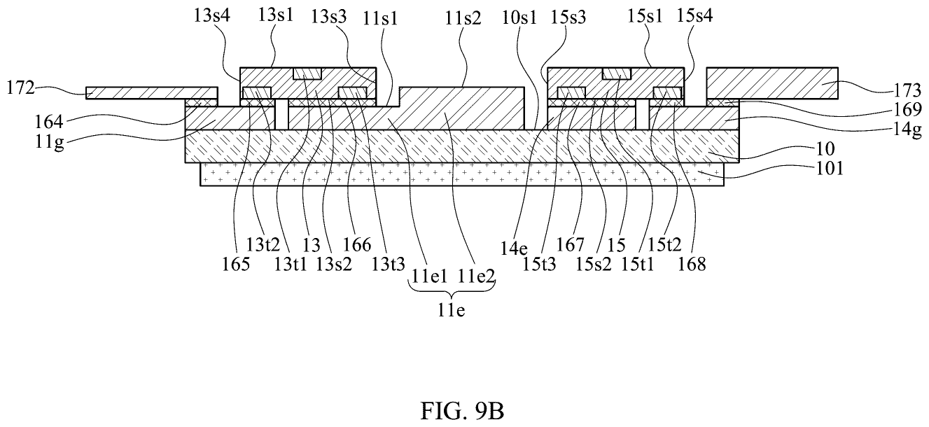

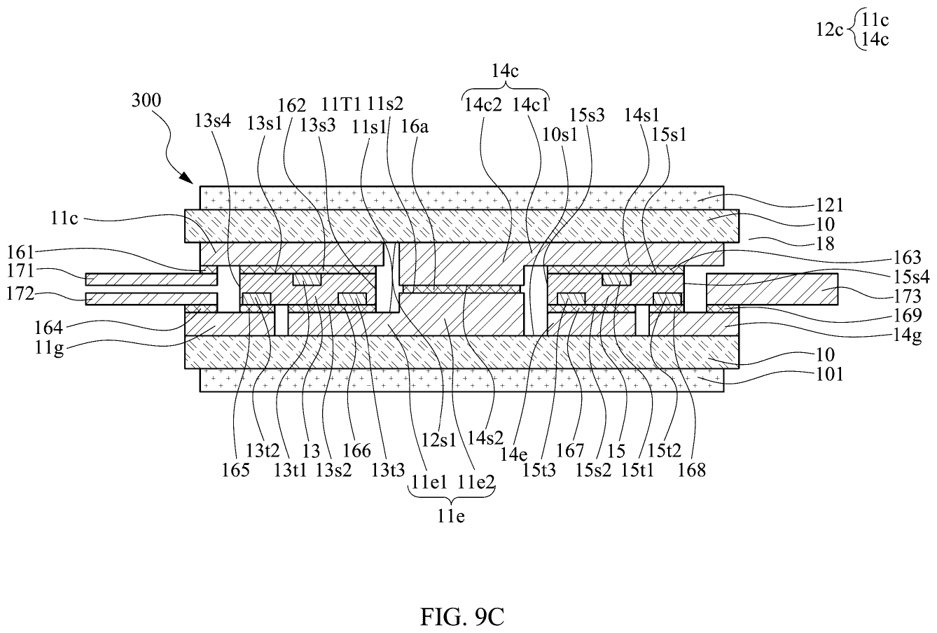

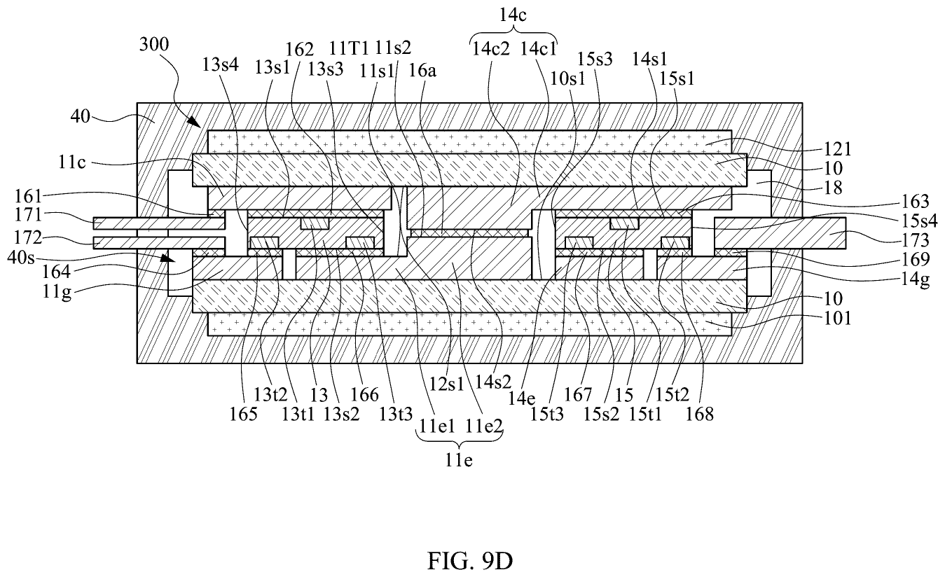

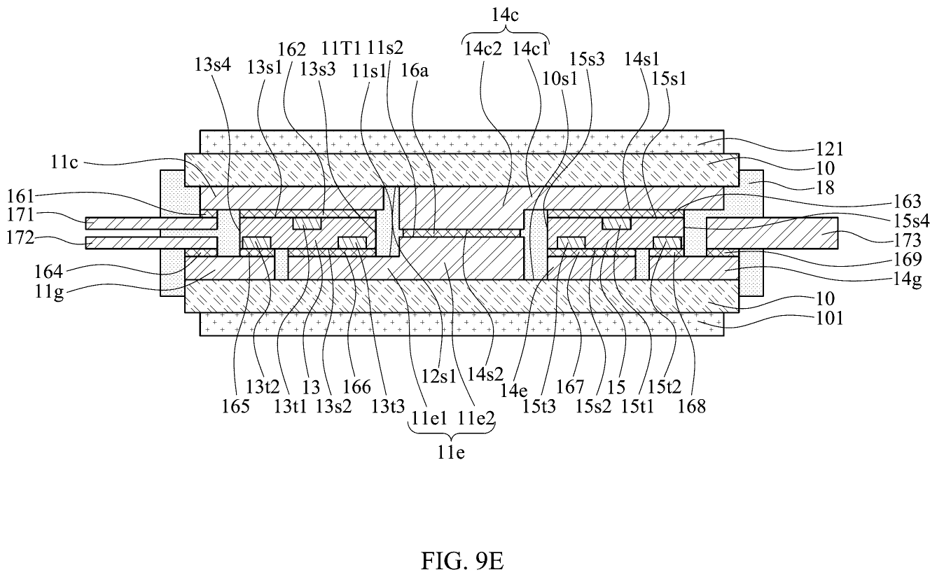

FIGS. 9A, 9B, 9C, 9D, and 9E illustrate one or more stages of an example of a method for manufacturing an electronic device (e.g., the electronic device 100A) according to some embodiments of the present disclosure.

As shown in FIG. 9A, a dielectric layer 10 may be provided. Conductive layers 11g, 11e, 14e, and 14g may be formed on a surface 10s1 of the dielectric layer 10. The conductive layers (or parts) 11g, 11e, 14e, 14g may refer to a first conductive layer 10c. A conductive layer 102 may be formed on a surface of the dielectric layer 10 opposite to the surface 10s1. The conductive layers 11g, 11e, 14e, 14g, and 102 may be formed by a direct bonded copper (DBC) process.

The conductive layers 11g, 11e, 14e, and 14g may include patterned conductive layers. The conductive layers 11g, 14e, and 14g may have a uniform thickness. The conductive layer 11e may have multiple thicknesses. The conductive layer 11e may have a first part 11e1 with a first thickness 11T1 and a second part 11e2 with a second thickness 11T2. The second thickness 11T2 is greater than the first thickness 11T1. The second thickness 11T2 may be greater than those of the conductive layers 11g, 14e, and 14g.

As shown in FIG. 9B, a die (or a power die) 13 may be formed on the first part 11e1 of the conductive layer 11e and the conductive layer 11g. The first part 11e1 and the conductive layer 11g may be connected to the die 13 through connection elements 165 and 166, respectively. The die 13 may include a collector terminal 13t1 at an upper surface 13s1 of the die 13, and a gate terminal 13t2 and an emitter terminal 13t3 at a lower surface 13s2 of the die 13. The gate terminal 13t2 may be connected to the conductive layer 11g. The emitter terminal 13t3 may be connected to the conductive layer 11e. A conductive element 172 may be formed on the conductive layer 11g. The conductive element 172 may be connected to the conductive layer 11g through a connection element 164. The conductive layer 11e may have a first upper surface 11s1 at the first part 11e1 and a second upper surface 11s2 at the second part 11e2. The first upper surface 11s1 may be covered by the die 13, and the second upper surface 11s2 is exposed. An elevation of the upper surface 11s2 of the second part 11e2 (facing away from the first part 11e1) may be lower than an elevation of the upper surface 13s1 of the die 13 (facing away from the first part 11e1) with respect to the first part 11e1.

In some embodiments, a die (or a power die) 15 may be formed on the conductive layer 14e and the conductive layer 14g. The conductive layer 14e and the conductive layer 14g may be connected to the die 15 through connection elements 167 and 168, respectively. The die 15 may include a collector terminal 15t1 at an upper surface 15s1 of the die 15, and a gate terminal 15t2 and an emitter terminal 15t3 at a lower surface 15s2 of the die 15. The gate terminal 15t2 may be connected to the conductive layer 14g. The emitter terminal 15t3 may be connected to the conductive layer 14e. A conductive element 173 may be formed on the conductive layer 14g. The conductive element 173 may be connected to the conductive layer 14g through a connection element 169.

As shown in FIG. 9C, a dielectric layer 12 may be provided. Conductive layers 11c and 14c may be formed on a surface 12s1 of the dielectric layer 12. The conductive layers (or parts) 11c and 14c may refer to a second conductive layer 12c. A conductive layer 122 may be formed on a surface of the dielectric layer 12 opposite to the surface 12s1. The conductive layers 11c, 14c, and 122 may be formed by a direct bonded copper (DBC) process.

The conductive layers 11c and 14c may include patterned conductive layers. The conductive layer 11c may have a uniform thickness. The conductive layer 14c may have multiple thicknesses. The conductive layer 14c may have a first part 14cl with a third thickness 14T1 and a second part 14c2 with a fourth thickness 14T2. The fourth thickness 14T2 is greater than the third thickness 14T1. The fourth thickness 14T2 may be greater than that of the conductive layer 11c.

In some embodiments, a conductive element 171 may be formed on the conductive layer 11c. The conductive element 171 may be connected to the conductive layer 11c through a connection element 161.

Furthermore, the dielectric layer 12 accompanied with the conductive layers 11c, 14c, and 122 may be bonded on the die 13 and die 15 to form an intermediate structure 300. In some embodiments, the conductive layer 11c may be bonded on the upper surface 13s1 of the die 13 through a connection element 162. The first part 14cl of the conductive layer 14c may be bonded on the upper surface 15s1 of the die 15 through a connection element 163. The second part 14c2 of the conductive layer 14c may be bonded on the second part 11e2 of the conductive layer 11e through a connection element 16a. Owing to the relatively large heights of the second part 11e2 and the second part 14c2, the conductive layer 14c connects to the conductive layer 11e without an additional spacer (or a pillar). The Z height of the intermediate structure 300 can be relatively low, and the manufacturing cost can be reduced.

As shown in FIG. 9D, the intermediate structure 300 including the dielectric layers 10 and 12, the conductive layers 101, 102, 11c, 11g, 11e, 14c, 14g, and 14e, the dies 13 and 15, and the conductive elements 171, 172, and 173 may be placed in a mold 40. The conductive elements 171, 172, and 173 may have ends exposed by the mold 40. The mold 40 may define a space 40s accompanying the dies 13 and 15 and the conductive layers 11c, 11g, 11e, 14c, 14g, and 14e, a half of the dielectric layer 10, and a half of the dielectric layer 12.

As shown in FIG. 9E, an encapsulating layer 18 may be formed in the space 40s to encapsulate the dies 13 and 15 and the conductive layers 11c, 11g, 11e, 14c, 14g, and 14e, a half of the dielectric layer 10, and a half of the dielectric layer 12. The intermediate structure 300 with the encapsulating layer 18 may be removed from the mold 40.

Afterwards, a heat dissipation structure 191 and a heat dissipation structure 192 are respectively formed on the conductive layers 121 and 101 to complete the electronic device 100A. The conductive layers 11e and 14c may be configured to dissipate heat from the die 13 and the die 15 to the heat dissipation structure 191 and the heat dissipation structure 192.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to #1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to #1%, less than or equal to ±0.5%, less than or equal to ±0.1%, or less than or equal to ±0.05%. For example, “substantially” perpendicular can refer to a range of angular variation relative to 90° that is less than or equal to #10°, such as less than or equal to ±5°, less than or equal to ±4°, less than or equal to ±3°, less than or equal to ±2°, less than or equal to #1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural references unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a first conductive layer comprising a first part and a second part separated from the first part; and
a first power die disposed above the first conductive layer and having a first surface, wherein the first power die comprises a first terminal exposed by the first surface and a second terminal exposed by the first surface,
wherein the first part is electrically connected to the first terminal and the second part is electrically connected to the second terminal.

2. The electronic device of claim 1, wherein the first power die comprises an insulated gate bipolar transistor (IGBT).

3. The electronic device of claim 2, wherein the first terminal is a gate terminal, and the second terminal is an emitter terminal.

4. The electronic device of claim 1, further comprising:
a second power die disposed above the first conductive layer; and
a second conductive layer disposed above the first power die and the second power die,
wherein the second power die is electrically connected to the first power die through the second conductive layer and the first conductive layer.

5. The electronic device of claim 4, further comprising a conductive element connecting the first conductive layer to the second conductive layer.

6. The electronic device of claim 1, further comprising a conductive element connected to the first part and configured to receive a signal external to the electronic device, wherein the first part is a conductive structure for bridging the conductive element and the first terminal.

7. The electronic device of claim 6, wherein the first part has a step structure, and a portion of the first part is disposed at a lateral side of the first power die.

8. The electronic device of claim 6, wherein a material of the first part comprises a solder material or a conductive paste.

9. An electronic device, comprising:
a first conductive layer;
a second conductive layer disposed over the first conductive layer and comprising a first part extending toward the first conductive layer;
a first die disposed between the first conductive layer and the second conductive layer, wherein a distance between the first conductive layer and the second conductive layer is substantially equal to a thickness of the first die; and
a second die disposed between the first conductive layer and the second conductive layer and electrically connected to the first die through the first part.

10. The electronic device of claim 9, wherein the first die and the second die are power dies.

11. The electronic device of claim 10, wherein the first die and the second die are connected in series.

12. The electronic device of claim 11, wherein an emitter terminal of the first die is electrically connected to a collector terminal of the second die.

13. The electronic device of claim 9, wherein the first part is disposed between the first die and the second die.

14. The electronic device of claim 9, wherein the first conductive layer comprises a first part extending toward the second conductive layer and connecting to the first part of the second conductive layer.

15. The electronic device of claim 9, wherein the second conductive layer comprises a second part extending from the first part, wherein the second die is disposed between the second part and the first conductive layer.

16. The electronic device of claim 15, wherein the second conductive layer comprises a third part spaced apart from the first part and electrically connected to the first die.

17. The electronic device of claim 16, wherein the third part and the first part are electrically connected to different functional terminals of the first die, respectively.

18. An electronic device, comprising:
a first die;
a second die disposed adjacent to the first die; and
a first conductive layer comprising a first part supporting the first die and a second part disposed at a lateral side of the first die,
wherein the second die is electrically connected to the first die through the second part.

19. The electronic device of claim 18, wherein the first die has an upper surface facing away from the first part and the second part has an upper surface, wherein an elevation of the upper surface of the second part is lower than an elevation of the upper surface of the first die with respect to the first part.

20. The electronic device of claim 18, further comprising an encapsulating layer covering the first die and the first conductive layer, wherein the first conductive layer comprises a third part spaced apart from the first part and protruding from the encapsulating layer.
